(19) United States
(12) Patent Application Publication
(10) Pub. No.: US 2025/0323656 A1
(43) Pub. Date: Oct. 16, 2025

(54) METHOD AND SYSTEM FOR PROCESSING SIGNALS FROM MULTIPLE ANALOG-TO-DIGITAL CONVERTERS

(71) Applicant: Microchip Technology Incorporated, Chandler, AZ (US)

(72) Inventors: Kjetil Kirkholt, Lensvik (NO); Amund Aune, Heimdal (NO); Henrik Nyholm, Trondheim (NO)

(73) Assignee: Microchip Technology Incorporated, Chandler, AZ (US)

(21) Appl. No.: 19/175,589

(22) Filed: Apr. 10, 2025

Related U.S. Application Data
(60) Provisional application No. 63/632,262, filed on Apr. 10, 2024.

(51) Int. Cl. H03M 1/12; G06F 7/02

(52) U.S. Cl. CPC H03M 1/1205; G06F 7/02

(57) ABSTRACT

A system for processing signals from multiple analog-to-digital converters (ADCs) is provided. The system may include a first ADC to receive a first input signal and convert the first input signal to a first digital signal, a second ADC to obtain a second input signal and convert the second input signal to a second digital signal, a control logic circuitry to receive one or more configuration settings of the first ADC and apply the one or more configuration settings to the second ADC, and a computation logic circuitry to generate one or more computational results in response to comparing the first digital signal and the second digital signal.

### CROSS-REFERENCE TO RELATED APPLICATION

The present application claims priority from U.S. Provisional Patent Application No. 63/632,262 filed on Apr. 10, 2024, which is incorporated herein by reference in its entirety.

### TECHNICAL FIELD

The present disclosure relates generally to signal processing, and more specifically to a method and system for processing signals from multiple analog-to-digital converters.

### SUMMARY

According to an aspect of one or more examples, there is provided a method for processing signals from multiple analog-to-digital converters (ADCs). The method may include receiving, at a first analog-to-digital converter (ADC), a first input signal to convert the first input signal to a first digital signal, receiving, at a second ADC, a second input signal to convert the second input signal to a second digital signal, receiving one or more configuration settings of the first ADC and applying the one or more configuration settings to the second ADC, comparing, at a computation logic circuitry, the first digital signal and the second digital signal, and generating one or more computational results responsive to the comparing of the first digital signal and the second digital signal.

The method may include generating a first accumulated digital value by adding samples of the first digital signal, and generating a second accumulated digital value by adding samples of the second digital signal. The comparing operation may include comparing the first accumulated digital value and the second accumulated digital value with one or more of a plurality of comparison thresholds, wherein the plurality of comparison thresholds comprises an accumulated low comparison threshold and an accumulated high comparison threshold.

The method may include storing a first sample digital value of the first digital signal, and storing a second sample digital value of the second digital signal. The comparing operation may include comparing the first sample digital value and the second sample digital signal with one or more of the plurality of comparison thresholds, wherein the plurality of comparison thresholds comprises a sample low comparison threshold and a sample high comparison threshold.

The comparing operation may include determining whether the first sample digital value and the second sample digital value fall within a sample range defined by the sample low comparison threshold and sample high comparison threshold, or whether the first accumulated digital value and the second accumulated digital value fall within an accumulated range defined by the accumulated low comparison threshold and accumulated high comparison threshold.

The method may include triggering at least one of an interrupt signal for a processor of a microcontroller and one or more safety events in response to at least one of the first sample digital value and the second sample digital value falling outside the sample range, or at least one of the first accumulated digital value and the second accumulated digital value falling outside the accumulated range.

The comparing operation may include performing an arithmetic operation on at least one of the first sample digital value, the second sample digital value, the first accumulated digital value, and the second accumulated digital value, and comparing a result of the arithmetic operation with one or more of the plurality of comparison thresholds, wherein the arithmetic operation is at least one of addition, subtraction, multiplication, division, averaging and scaling.

The method may include receiving the first input signal and outputting the second input signal corresponding to a delayed version of the first input signal. The second input signal obtained by the second ADC may be the same as the first input signal received by the first ADC.

The comparing operation may include comparing the first digital signal with the second digital signal and triggering at least one of an interrupt signal for a processor of a microcontroller and one or more safety events in response to determining that a difference between the first digital signal and the second digital signal exceeds one or more of a plurality of comparison thresholds.

According to an aspect of one or more examples, there is provided a system for processing signals from multiple analog-to-digital converters (ADCs). The system may include a first ADC to receive a first input signal and convert the first input signal to a first digital signal, a second ADC to obtain a second input signal and convert the second input signal to a second digital signal, a control logic circuitry to receive one or more configuration settings of the first ADC and apply the one or more configuration settings to the second ADC, and a computation logic circuitry to generate one or more computational results in response to comparing the first digital signal and the second digital signal.

The system may include a first accumulator to generate a first accumulated digital value by adding samples of the first digital signal, and a second accumulator to generate a second accumulated digital value by adding samples of the second digital signal. The computation logic circuitry may compare the first accumulated digital value and the second accumulated digital value with one or more of a plurality of comparison thresholds, wherein the plurality of comparison thresholds include an accumulated low comparison threshold and an accumulated high comparison threshold.

The system may include a first sample register to store a first sample digital value of the first digital signal, and a second sample register to store a second sample digital value of the second digital signal. The computation logic circuitry may compare the first sample digital value and the second sample digital signal with one or more of the plurality of comparison thresholds, wherein the plurality of comparison thresholds includes a sample low comparison threshold and a sample high comparison threshold.

The computation logic circuitry may determine whether the first sample digital value and the second sample digital value fall within a sample range defined by the sample low comparison threshold and sample high comparison threshold, or whether the first accumulated digital value and the second accumulated digital value fall within an accumulated range defined by the accumulated low comparison threshold and accumulated high comparison threshold. The computation logic circuitry may trigger at least one of an interrupt signal for a processor of a microcontroller and one or more safety events in response to at least one of the first sample digital value and the second sample digital value falling outside the sample range, or at least one of the first accumulated digital value and the second accumulated digital value falling outside the accumulated range.

The computation logic circuitry may perform an arithmetic operation on at least one of the first sample digital value, the second sample digital value, the first accumulated digital value, and the second accumulated digital value, and compare a result of the arithmetic operation with one or more of the plurality of comparison thresholds. The arithmetic operation may be at least one of addition, subtraction, multiplication, division, averaging, and scaling.

The system may include a delay circuit to receive the first input signal and output the second input signal corresponding to a delayed version of the first input signal. The second input signal obtained by the second ADC may be the same as the first input signal received by the first ADC.

The computation logic circuitry may compare the first digital signal with the second digital signal, wherein the computation logic circuitry is to trigger at least one of an interrupt signal for a processor of a microcontroller and one or more safety events in response to determining that a difference between the first digital signal and the second digital signal exceeds one or more of a plurality of comparison thresholds.

The computation logic circuitry may include a window comparator low register to store a plurality of low comparison thresholds, and a window comparator high register to store a plurality of high comparison thresholds.

According to an aspect of one or more examples, there is provided a system for processing signals from multiple analog-to-digital converters (ADCs). The system may include a first ADC to receive a first input signal and convert the first input signal to a first digital signal, a second ADC to obtain a second input signal and convert the second input signal to a second digital signal, a control logic circuitry to receive one or more configuration settings of the first ADC and apply the one or more configuration settings to the second ADC, and a computation logic circuitry to generate one or more computational results in response to comparing the first digital signal and the second digital signal. The computation logic circuitry may perform an arithmetic operation on at least one of the first sample digital value from the first digital signal and a second sample digital value from the second digital signal, and compare a result of the arithmetic operation with one or more of a plurality of comparison thresholds.

### BRIEF DESCRIPTION OF DRAWINGS

FIG. 1 shows a block diagram illustrating a system for processing multiple input signals according to one or more examples.

FIG. 2 shows a block diagram illustrating a method for processing multiple input signals according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

In systems used in Functional Safety (FuSa) applications, concurrent operation of multiple Analog-to-Digital converters (ADCs) can be used to provide redundancy and achieve a high level of safety integrity. However, providing such redundancy involves using multiple analog peripherals, which consumes time and memory resources while processing data from the multiple ADCs, increasing complexity and CPU intervention. Therefore, there is a need for a method and system for performing computation of signals from multiple ADCs.

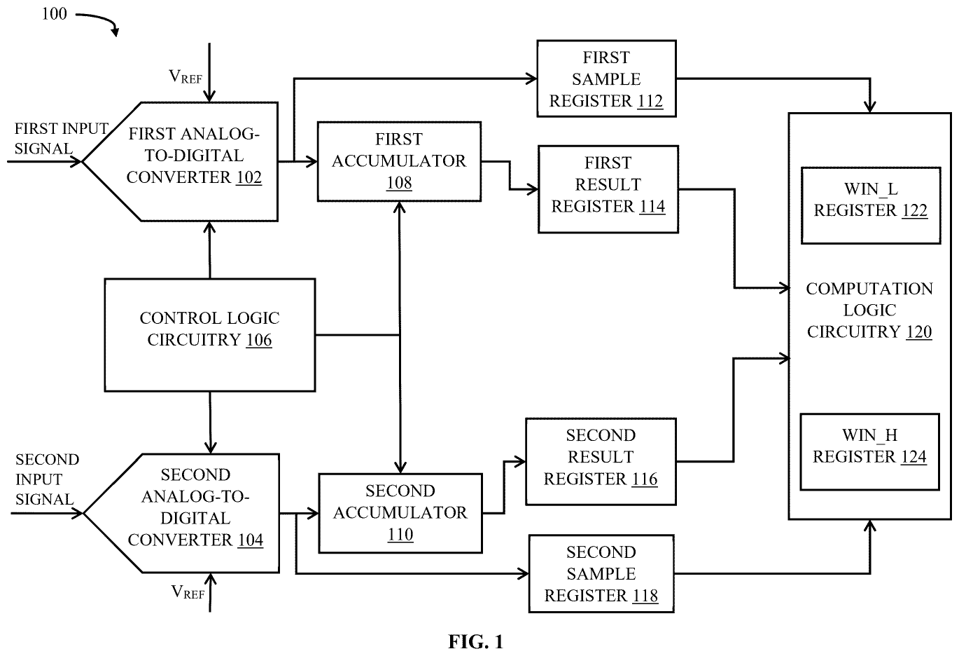

FIG. 1 shows a block diagram illustrating a system 100 for processing multiple input signals according to one or more examples. The system 100 may leverage a combination of hardware components, control logic and computation logic, to process the input signals. The system 100 may include a first ADC 102, a second ADC 104, a control logic circuitry 106, a first accumulator 108, a second accumulator 110, a first sample register 112, a first result register 114, a second result register 116, a second sample register 118 and a computation logic circuitry 120. Although the example system 100 of FIG. 1 only includes two ADCs (102, 104), any number of ADCs may be used.

In one or more examples, the first ADC 102 may be an 8-bit ADC. However, one of ordinary skill in the art will understand that any resolution ADC may be used. The first ADC 102 may receive a first input signal. The first input signal may be a differential input signal or a single-ended analog input signal, without limitation. The first ADC 102 may include a first programmable gain amplifier (PGA) or first operational amplifier (not shown) to amplify the first input signal. The first ADC 102 may be operatively coupled to a first analog input multiplexer (not shown) to receive the first input signal. The first ADC 102 may be provided with a voltage reference (V_{ref}) through a first analog reference pin. The voltage reference for the first ADC 102 may control a conversion range of the first ADC 102. The first ADC 102 may convert the first input signal to a first digital signal.

In one or more examples, the second ADC 104 may be an 8-bit ADC. However, one of ordinary skill in the art will understand that any resolution ADC may be used. The second ADC 104 may obtain a second input signal. The second input signal may be a differential input signal or a single-ended analog input signal, without limitation. The second ADC 104 may include a second programmable gain amplifier (PGA) or second operational amplifier to amplify the second input signal. The second ADC 104 may be operatively coupled to a second analog input multiplexer to obtain the second input signal. The second ADC 104 may be provided with a voltage reference (V_{ref}) through a second analog reference pin. The voltage reference of the second ADC 104 may control a conversion range of the second ADC 104. The second ADC 104 may convert the second input signal to a second digital signal.

The control logic circuitry 106 may be operatively coupled with the first ADC 102, the second ADC 104, the first accumulator 108 and the second accumulator 110. The control logic circuitry 106 may send an enable signal and a gain setting to the first PGA and the second PGA, or the first and second operational amplifiers, to amplify the first input signal and the second input signal, respectively. The control logic circuitry may enable the first ADC 102 and the second ADC 104 to convert the first input signal and the second input signal, respectively. The control logic circuitry 106 may determine a number of samples to be accumulated by the first accumulator 108 and the second accumulator 110. The control logic circuitry 106 may send one or more control signals to the first accumulator 108 and the second accumulator 110 specifying the number of samples to accumulate. According to various examples in which the same input signal is provided to the first ADC 102 and the second ADC 104, the control logic circuitry 106 may send one or more control signals to one or more of the first ADC 102, the second ADC 104, the first accumulator 108, and the second accumulator 110 to interleave measurements of the input signal to effectively increase the sampling speed. According to various examples, the control logic circuitry 106 may include configuration settings for the first ADC 102 that may be provided by software executed by a processor on a microcontroller. The control logic circuitry 106 may cause the second ADC 104 to inherit the configuration settings of the first ADC 102, so that the software does not need to provide configuration settings to both the first ADC 102 and the second ADC 104. According to various examples, the software executed by a processor on a microcontroller may provide configuration settings directly to the first ADC 102. Alternatively, the control logic circuitry 106 may cause the first ADC 102 to inherit the configuration settings of the second ADC 104, so that the software does not need to provide configuration settings to both the first and second ADCs 102, 104.

According to various examples, the control logic circuitry may include delay circuitry (not shown) that may delay triggering of the first and second ADCs 102 and 104 so that the first and second ADCs 102 and 104 may sample the first and second input signals (which may the same in various examples) at different times. Delaying the sample times may increase separation so that a failure event affecting the first and second input signals or the first and second ADCs 102 and 104 may be detected by the computational logic circuitry 120. For example, if the first and second ADCs 102 and 104 experienced radiation at the same time, their output sample may be increased. By delaying the sampling time, the difference may be detected by the computational logic circuitry 120.

According to various examples, the input signals may be delayed with respect to each other. For example, a time delay may be established between the first input signal received by the first ADC 102 and the second input signal obtained by the second ADC 104. In various examples in which the second input signal is a time-delayed version of the first input signal, the temporally distinct reception of the same input signal using the first ADC 102 and the second ADC 104 may avoid one or more failure events that may affect the first ADC 102 and the second ADC 104 simultaneously.

The first accumulator 108 may be operatively coupled with the first ADC 102 and the first result register 114. The first accumulator 108 may accumulate a first predetermined number of digital samples from the first ADC 102 based on one or more control signals from the control logic circuitry 106 to generate a first accumulated digital value. A first sample digital value may be associated with each of the first predetermined number of digital samples. The first accumulator 108 may perform at least one of a series accumulation and a burst accumulation of the first predetermined number of digital samples. In the series accumulation, the first ADC 102 samples one sample of the first input signal based on a control signal or “trigger” from the control logic circuitry 106, and the accumulator 108 may sequentially add each new sample received from the first ADC 102 until the first predetermined number of digital samples is reached. For series accumulation, the first ADC 102 will receive ‘n’ triggers from the control logic circuitry 106 to sample ‘n’ samples from the first input signal. In the burst accumulation, the first ADC 102 may sample ‘n’ samples of the first input signal based on one trigger from the control logic circuitry 106, and the first accumulator 108 may accumulate the first predetermined number of digital samples to generate the first accumulated digital value.

The second accumulator 110 may be operatively coupled with the second ADC 104 and the second result register 116. The second accumulator 110 may accumulate a second predetermined number of digital samples from the second ADC 104 based on one or more control signals from the control logic circuitry 106 to generate a second accumulated digital value. A second sample digital value may be associated with each of the second predetermined number of digital samples. The second accumulator 110 may perform at least one of a series accumulation and a burst accumulation of the second predetermined number of digital samples. In the series accumulation, the second accumulator 110 may sequentially add each new sample received from the second ADC 104 until the second predetermined number of digital samples is reached. In the burst accumulation, the second accumulator 110 may accumulate the second predetermined number of digital samples simultaneously to generate the second accumulated digital value.

The first sample register 112 and the first result register 114 may store the first sample digital value and the first accumulated digital value, respectively. The first digital signal output by the first ADC 102 may correspond to at least one of the first sample digital value and the first accumulated digital value. The second sample register 118 and the second result register 116 may store the second sample digital value and the second accumulated digital value, respectively. The second digital signal output by the second ADC 104 may correspond to at least one of the second sample digital value and the second accumulated digital value.

The computation logic circuitry 120 may include a window comparator low register (WIN_L) 122 and a window comparator high register (WIN_H) 124 to respectively store sets of comparison thresholds, which may be pre-defined according to various examples. The sets of comparison thresholds may include a low comparison threshold and a high comparison threshold for various comparisons to be performed by the computation logic circuitry 120. For example, the comparison thresholds may include accumulated thresholds for comparing against the first and second accumulated digital values. According to various examples, the comparison thresholds may include sample thresholds for comparing against the first and second sample digital values. The low comparison thresholds may be stored in the window comparator low register (WIN_L) 122 and the high comparison thresholds may be stored in the window comparator high register (WIN_H) 124. The computation logic circuitry 120 may compare the first digital signal and the second digital signal with the set of comparison thresholds.

For example, the computation logic circuitry 120 may determine whether the first digital signal and the second digital signal fall within a predetermined range defined by the low comparison threshold and the high comparison threshold of the set of pre-defined comparison thresholds or outside the predetermined range. The computation logic circuitry 120 may trigger at least one of an interrupt signal for a processor of a microcontroller and one or more safety events if at least one of the first digital signal and the second digital signal fall outside the predetermined range. The computation logic circuitry 120 may perform an arithmetic operation on the first digital signal and the second digital signal. The arithmetic operation may be at least one of addition, subtraction, multiplication, division, averaging and scaling.

According to various examples, the computation logic circuitry 120 may perform one or more arithmetic operations on the first and second accumulated digital values, and compare the result of the one or more arithmetic operations to the low and high comparison thresholds. For example, the computation logic circuitry 120 may subtract the second accumulated digital value from the first accumulated digital value and compare the difference to the low and high comparison thresholds. If the difference falls outside of the range between the low and high comparison thresholds, the computation logic circuitry 120 may trigger at least one of an interrupt signal for a processor of a microcontroller and one or more safety events indicating that the first and second accumulated digital values differ more than is expected or acceptable. Although the above example subtracted the first and second accumulated digital values, one skilled in the art would understand that various arithmetic operations may be used, and the results may be compared to corresponding low and high comparison thresholds.

According to various examples, the computation logic circuitry 120 may perform one or more arithmetic operations on the first and second sample digital values respectively stored in the first sample register 112 and the second sample register 118, and compare the result of the one or more arithmetic operations to the corresponding low and high comparison thresholds. For example, the computation logic circuitry 120 may subtract the second sample digital value from the first sample digital value and compare the difference to the corresponding low and high comparison thresholds. If the difference falls outside of the range between the low and high comparison thresholds, the computation logic circuitry 120 may trigger at least one of an interrupt signal for a processor of a microcontroller and one or more safety events indicating that the first and second sample digital values differ more than is expected or acceptable. Although the above example subtracted the first and second sample digital values, one skilled in the art would understand that various arithmetic operations may be used, and the results may be compared to corresponding low and high comparison thresholds.

In one or more example embodiments, the computation logic circuitry 120 may compare the first digital signal with the second digital signal when the second input signal obtained by the second ADC 104 is the same as the first input signal received by the first ADC 102. For example, the second ADC 104 may be a shadow ADC of the first ADC 102 that may be used to provide redundancy and confirm the accuracy of the first digital signal. According to various examples, the computation logic circuitry 120 may trigger at least one of the interrupt signal for the processor of the microcontroller and the one or more safety events if the first digital signal is different from the second digital signal. According to various examples in which more than two ADCs are used, the computational logic circuitry 120 may compare a plurality of digital signals from the respective ADCs to each other or to one or more comparison thresholds. The computational logic circuitry 120 may employ a majority “voting” process in which the determination to trigger an interrupt signal or a safety event is based on a comparison result of a majority of the digital signals. For example, in a system using three ADCs that receive the same input signal, if the computational logic circuitry 120 determines that two of the digital signals match or the difference between then is within a comparison threshold, but the third digital signal does not match the other two digital signals (or the difference between the third digital signal and the first two digital signals exceeds the comparison threshold), the computational logic circuitry may determine not to trigger an interrupt signal or a safety event. One skilled in the art would understand that various other types of logic decision algorithms are possible based on the plurality of digital signals received from the plurality of ADCs, including comparisons of sampled digital values from the plurality of digital signals or accumulated values of the plurality of digital signals. By using the computation logic circuitry 120 to compare the first and second digital signals, software executed on a processor in a microcontroller does not need to compare the two digital signals or compare the digital signals to thresholds, so that software overhead and load on the microcontroller may be reduced.

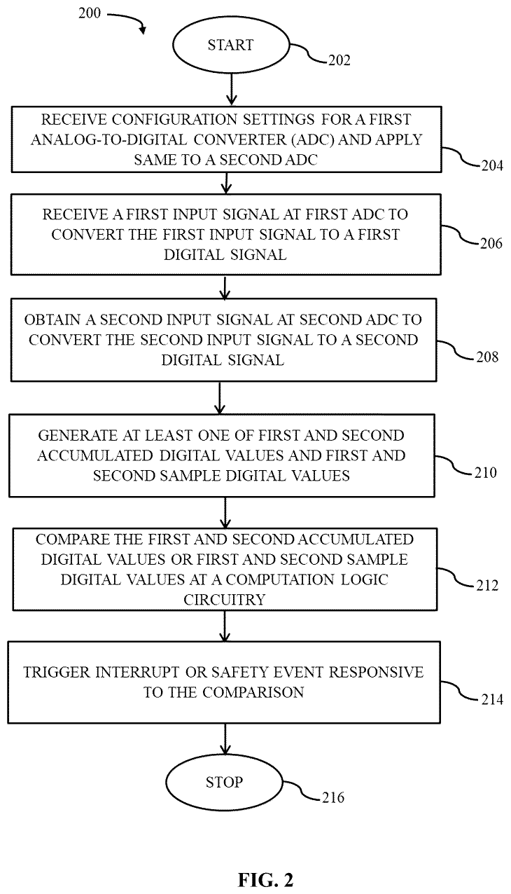

FIG. 2 shows a flowchart 300 illustrating a method for processing multiple input signals according to one or more examples. It may be noted that in order to explain the method operations of the flowchart 200, references will be made to the elements explained in one or more of FIG. 1 and FIG. 2.

The flowchart 200 starts at operation 202. At operation 204, the method may include receiving configuration settings for the first ADC 102 and applying the configuration settings to the second ADC 104. According to various examples, software executed by a processor on a microcontroller may provide the configuration settings to the first ADC 102, but by using, for example, control logic circuitry 106 to apply the configuration settings to the second ADC 104, which may reduce the software overhead and processor load. At operation 206, the method may include receiving a first input signal at the first ADC 102 to convert the first input signal to a first digital signal. At operation 208, the method may include obtaining a second input signal at the second ADC 104 to convert the second input signal to a second digital signal. At operation 210, the method may include generating at least one of first and second accumulated digital values, and first and second sample digital values. At operation 212, the method may include comparing the first and second accumulated digital values or the first and second sample digital values at the computation logic circuitry 120. For example, the comparison may include one or more of comparing the first and second sample (or accumulated) digital values to each other, and comparing the first and second sample (or accumulated) digital values to one or more comparison thresholds. According to various examples, the comparison operation 212 may include performing one or more arithmetic operations on the first and second sample (or accumulated) digital values, and comparing the result of the arithmetic operation(s) to the one or more comparison thresholds. At operation 214, the method may include one or more of triggering an interrupt and a safety event responsive to the comparison operation 212.

The flowchart 200 terminates at operation 216. It may be noted that the flowchart 200 is explained to have the above-stated process operations; however, those skilled in the art would appreciate that the flowchart 200 may have more/less number of process operations which may enable all the above stated examples of the present disclosure.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of these examples herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A method for processing signals from multiple analog-to-digital converters (ADCs), the method comprising:
receiving, at a first analog-to-digital converter (ADC), a first input signal to convert the first input signal to a first digital signal;
receiving, at a second ADC, a second input signal to convert the second input signal to a second digital signal;
receiving one or more configuration settings of the first ADC and applying the one or more configuration settings to the second ADC;
comparing, at a computation logic circuitry, the first digital signal and the second digital signal; and
generating one or more computational results responsive to the comparing of the first digital signal and the second digital signal.

2. The method of claim 1, comprising:
generating a first accumulated digital value by adding samples of the first digital signal; and
generating a second accumulated digital value by adding samples of the second digital signal;
wherein the comparing operation comprises comparing the first accumulated digital value and the second accumulated digital value with one or more of a plurality of comparison thresholds, wherein the plurality of comparison thresholds comprises an accumulated low comparison threshold and an accumulated high comparison threshold.

3. The method of claim 2, comprising:
storing a first sample digital value of the first digital signal; and
storing a second sample digital value of the second digital signal;
wherein the comparing operation comprises comparing the first sample digital value and the second sample digital signal with one or more of the plurality of comparison thresholds, wherein the plurality of comparison thresholds comprises a sample low comparison threshold and a sample high comparison threshold.

4. The method of claim 3, wherein the comparing operation comprises determining whether the first sample digital value and the second sample digital value fall within a sample range defined by the sample low comparison threshold and sample high comparison threshold, or whether the first accumulated digital value and the second accumulated digital value fall within an accumulated range defined by the accumulated low comparison threshold and accumulated high comparison threshold.

5. The method of claim 3, comprising triggering at least one of an interrupt signal for a processor of a microcontroller and one or more safety events in response to at least one of the first sample digital value and the second sample digital value falling outside the sample range, or at least one of the first accumulated digital value and the second accumulated digital value falling outside the accumulated range.

6. The method of claim 1, wherein the comparing operation comprises performing an arithmetic operation on at least one of the first sample digital value, the second sample digital value, the first accumulated digital value, and the second accumulated digital value, and comparing a result of the arithmetic operation with one or more of the plurality of comparison thresholds;
wherein the arithmetic operation is at least one of addition, subtraction, multiplication, division, averaging and scaling.

7. The method of claim 1, comprising receiving the first input signal and outputting the second input signal corresponding to a delayed version of the first input signal.

8. The method of claim 1, wherein the second input signal obtained by the second ADC is the same as the first input signal received by the first ADC.

9. The method of claim 8, wherein the comparing operation comprises comparing the first digital signal with the second digital signal and triggering at least one of an interrupt signal for a processor of a microcontroller and one or more safety events in response to determining that a difference between the first digital signal and the second digital signal exceeds one or more of a plurality of comparison thresholds.

10. A system for processing signals from multiple analog-to-digital converters (ADCs), the system comprising:
a first ADC to receive a first input signal and convert the first input signal to a first digital signal;
a second ADC to obtain a second input signal and convert the second input signal to a second digital signal;
a control logic circuitry to receive one or more configuration settings of the first ADC and apply the one or more configuration settings to the second ADC; and
a computation logic circuitry to generate one or more computational results in response to comparing the first digital signal and the second digital signal.

11. The system of claim 10, comprising:
a first accumulator to generate a first accumulated digital value by adding samples of the first digital signal; and
a second accumulator to generate a second accumulated digital value by adding samples of the second digital signal;
wherein the computation logic circuitry is to compare the first accumulated digital value and the second accumulated digital value with one or more of a plurality of comparison thresholds, wherein the plurality of comparison thresholds comprise an accumulated low comparison threshold and an accumulated high comparison threshold.

12. The system of claim 11, comprising:
a first sample register to store a first sample digital value of the first digital signal; and
a second sample register to store a second sample digital value of the second digital signal;
wherein the computation logic circuitry is to compare the first sample digital value and the second sample digital signal with one or more of the plurality of comparison thresholds, wherein the plurality of comparison thresholds comprises a sample low comparison threshold and a sample high comparison threshold.

13. The system of claim 12, wherein the computation logic circuitry is to determine whether the first sample digital value and the second sample digital value fall within a sample range defined by the sample low comparison threshold and sample high comparison threshold, or whether the first accumulated digital value and the second accumulated digital value fall within an accumulated range defined by the accumulated low comparison threshold and accumulated high comparison threshold.

14. The system of claim 13, wherein the computation logic circuitry is to trigger at least one of an interrupt signal for a processor of a microcontroller and one or more safety events in response to at least one of the first sample digital value and the second sample digital value falling outside the sample range, or at least one of the first accumulated digital value and the second accumulated digital value falling outside the accumulated range.

15. The system of claim 12, wherein the computation logic circuitry is to perform an arithmetic operation on at least one of the first sample digital value, the second sample digital value, the first accumulated digital value, and the second accumulated digital value, and compare a result of the arithmetic operation with one or more of the plurality of comparison thresholds;
wherein the arithmetic operation is at least one of addition, subtraction, multiplication, division, averaging, and scaling.

16. The system of claim 10, comprising a delay circuit to receive the first input signal and output the second input signal corresponding to a delayed version of the first input signal.

17. The system of claim 10, wherein the second input signal obtained by the second ADC is the same as the first input signal received by the first ADC.

18. The system of claim 17, wherein the computation logic circuitry is to compare the first digital signal with the second digital signal, wherein the computation logic circuitry is to trigger at least one of an interrupt signal for a processor of a microcontroller and one or more safety events in response to determining that a difference between the first digital signal and the second digital signal exceeds one or more of a plurality of comparison thresholds.

19. The system of claim 11, wherein the computation logic circuitry comprises a window comparator low register to store a plurality of low comparison thresholds, and a window comparator high register to store a plurality of high comparison thresholds.

20. A system for processing signals from multiple analog-to-digital converters (ADCs), the system comprising:
a first ADC to receive a first input signal and convert the first input signal to a first digital signal;
a second ADC to obtain a second input signal and convert the second input signal to a second digital signal;
a control logic circuitry to receive one or more configuration settings of the first ADC and apply the one or more configuration settings to the second ADC; and
a computation logic circuitry to generate one or more computational results in response to comparing the first digital signal and the second digital signal;
wherein the computation logic circuitry is to perform an arithmetic operation on at least one of the first sample digital value from the first digital signal and a second sample digital value from the second digital signal, and compare a result of the arithmetic operation with one or more of a plurality of comparison thresholds.
